(19) United States
(12) Patent Application Publication
(10) Pub. No.: US 2025/0380363 A1
(43) Pub. Date: Dec. 11, 2025

(54) SYSTEM AND METHOD FOR RAPID HARDWARE APPLICATION DEVELOPMENT AND DEPLOYMENT

(71) Applicant: Northern Mechatronics Inc., Kitchener (CA)

(72) Inventors: Joshua Kwan Ho WONG, Waterloo (CA); Lucia IANNANTUONO, Waterloo (CA)

(21) Appl. No.: 19/233,637

(22) Filed: Jun. 10, 2025

Related U.S. Application Data
(60) Provisional application No. 63/658,030, filed on Jun. 10, 2024.

(51) Int. Cl. H05K 1/14; H05K 1/02; H05K 1/03

(52) U.S. Cl. CPC H05K 1/144; H05K 1/0215; H05K 1/0393

(57) ABSTRACT

Disclosed herein is a system and method for rapid hardware application development and deployment using modular/stackable electronic circuit boards or printed circuit boards (PCBs). The stackable PCBs can be snapped (or stacked) together to create a larger integrated electronic circuit. The stackable PCBs consist of a PCB, RF transceivers, conductive contact pads, matching circuits and a region to receive the conductive shapes of the PCB and non-RF connectors.

### CROSS REFERENCE TO RELATED APPLICATIONS

This application claims priority to and the benefit of U.S. Provisional Patent Application Ser. No. 63/658,030, entitled “SYSTEM AND METHOD FOR RAPID HARDWARE APPLICATION DEVELOPMENT AND DEPLOYMENT” filed on Jun. 10, 2024, the disclosure of which is incorporated herein by reference in its entirety.

### BACKGROUND

The present disclosure generally relates to the field of wireless communications systems, and more particularly, to the interconnection of radio frequency (RF) sub-systems and related methods.

Typical hardware development cycles often include a prototyping phase where a small quantity of devices is used to perform feasibility studies, complete the product design, perform field trials or explore market acceptance.

Many generic hardware prototyping solutions exist, including popular boards from Arduino, Raspberry Pi, etc. These boards are often too big in size and not robust enough to deploy in a real product usage case. These boards also possess many extraneous onboard peripherals (to allow a single product to cater to a wide range of applications) that make it difficult to properly represent the end application operating conditions such as battery power consumption. They also require duplicated investments and time spent on research and development to complete both a feasibility phase and a subsequent prototyping phase in the product design process.

Using a tire pressure sensor as an example, a field trial using an Arduino board means a large board with fly-wiring connected to a pressure sensor board and a battery pack is needed. This solution is bulky and difficult to attach to a vehicle tire, and this prototyping approach does not accurately indicate key performance metrics like power consumption as they would be measured in the real end product.

There is a desire for modular design of electronic circuit boards or printed circuit boards (PCBs) that can support different peripherals.

### BRIEF DESCRIPTION OF THE DRAWINGS

FIG. 1 is a front and back plan view of the Petal core, an exemplary printed circuit board with a processor and a transceiver.

FIG. 2 is a front and back plan view of the environment sensor Petal, an exemplary printed circuit board with an IMU, magnetometer, and an environment sensor.

FIG. 3 is a detailed view of the Petal core.

FIG. 4 is a front and back plan view of the power Petal, an exemplary printed circuit board with a battery charger circuit.

FIG. 5 is a view of a core Petal, an environment sensor Petal, and a power Petal stacked together.

FIG. 6 is a diagram illustrating a battery connected to the core, environment sensor and power Petal stack.

FIGS. 7A and 7B are diagrams illustrating Petal core stacked onto a development board.

FIG. 8 is a close-up view of the impedance control.

### SUMMARY

Disclosed herein is a system and method for rapid hardware application development and deployment using modular/stackable electronic circuit boards or printed circuit boards (PCBs). Each stackable PCB consists of different application specific circuits. PCBs having different functions can be stacked together to create a larger integrated unit with expanded functionalities.

### DETAILED DESCRIPTION

This disclosure addresses the gap between concept and field trials by creating an ecosystem of unique building blocks of circuit boards with different peripherals that could be quickly snapped together to create a desired application, in a compact form factor and containing the correct components to evaluate feasibility using a fully representative prototype.

This disclosure is an ecosystem of small circuit boards with a pre-defined interconnecting interface that allows each board to connect to one or more other boards. Each circuit board is populated with different sensors or circuits to serve different functions. A developer can quickly construct a custom application by snapping multiple boards together. This system is referred to by the trademark Petal.

Consider an example where the target application is an Internet of Things (IoT) device which measures temperature and reports the measurement to a server over LoRaWAN. A user would first select a sensor board with a temperature sensor, then snap on a module board which contains an application processor and a LoRaWAN radio, and then snap on a power board that interfaces with a battery. The processor and sensor boards can be plugged onto an accompanying development board for rapid firmware development. Once firmware development is completed, the processor and sensor can be removed from the development board and stacked onto the power board with a battery attached, and the entire stack can be assembled in a plastic (or other) housing for field deployment.

The present description is made with reference to the accompanying drawings, in which embodiments are shown. However, many different embodiments may be used, and thus the description should not be construed as limited to the embodiments set forth herein. Rather, these embodiments are provided so that this disclosure will be thorough and complete.

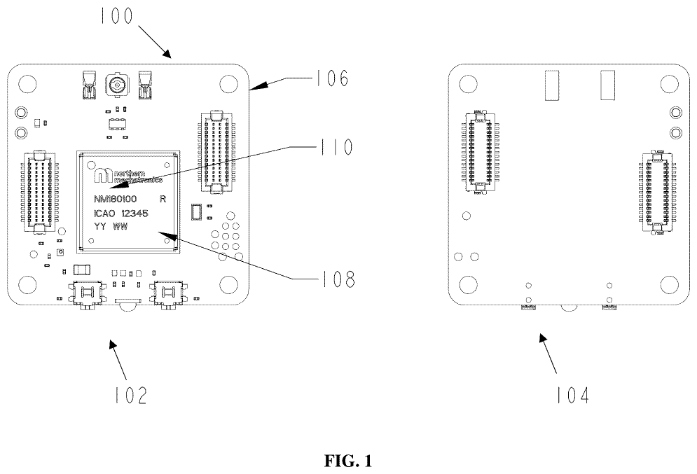

FIG. 1 is a front plan view 102 and back plan view 104 of the Petal core 100, an exemplary printed circuit board 106 with a processor 108 and a transceiver 110.

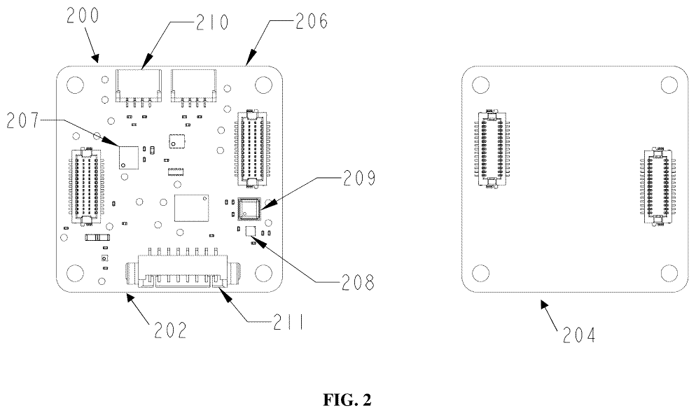

FIG. 2 is a front plan view 202 and back plan view 204 of the environment sensor Petal 200, an exemplary printed circuit board 206 with an IMU 207, magnetometer 208, an environment sensor 209, and different sizes connectors 210 and 211 to expand circuit functions.

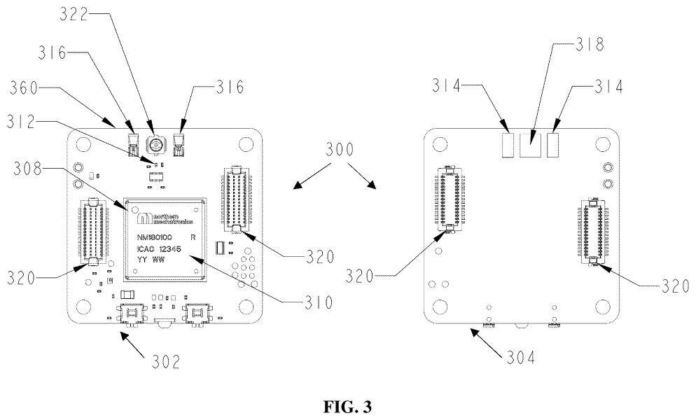

FIG. 3 is a detailed view of the Petal core. According to FIG. 3, detailed Petal core 300 is shown with a printed circuit board 306 having a front plan view 302 and back plan view 304. Printed circuit board 306 further comprises a transceiver 308, one or more processors 310, RF matching circuit 312, conductive pads 314, conductive connectors 316 and coaxial connector 322. RF matching circuit 312 couples between the conductive pads 314, the conductive connectors 316 and the transceiver 308.

According to FIG. 3, printed circuit board 306 further comprises conductive element 318 that is shaped in the inner layer of the printed circuit board 306. Detailed Petal core 300 further comprises multiple low frequency connectors 320 that allow multiple Petal boards to be stacked on top of one another.

According to the disclosure, multiple Petal boards are stacked on top of one another by means of low profile multiple low frequency connectors 320 that are also non-RF connectors with multiple options of mating height. For flexibility of integrating into an end-product, the core Petal in FIG. 3 has conductive connectors 316 on the top of the PCB 306, and also conductive pads 314 on the bottom of the PCB 306. These contact pads (i.e., conductive pads 314 and conductive connectors 316) provide flexibility to couple the transceiver to an antenna located on top of or below the PCB, or to an additional RF amplification stage. Furthermore, the present embodiment also includes a coaxial connector 322 allowing the product designer to couple an antenna or another RF system through a coaxial cable.

According to FIG. 3, to ensure proper RF operation regardless of the antenna embodiment, conductive element 318 is an example embodiment of conductive shapes located in the inner layer of the PCB 306 to present the optimal impedance to the transceiver. In the present embodiment, the target impedance is 50 Ohms. This is achieved by means of a conductive element 318, embedded in PCB 306 to maintain a similar electric field distribution regardless of which conductive pads or coaxial connector are being used for the antenna connection. The shape serves as a common reference for all the connections, enforcing a transverse electro-magnetic field distribution between the common conductive element 318 (i.e., conductive shape) to any one of the conductive pads (conductive pads 314 and conductive connectors 316) or the coaxial connector 322 when an antenna is connected while maintaining a high impedance when the antenna is disconnected.

According to FIG. 3, multiple low frequency connectors 320 are non-RF connectors. Different connector genders are used on the top and the bottom layer allowing each Petal to be stacked on top of one another. Furthermore, the connectors 320 on the same layer are offset from each other. This serves as a keying feature for the user to ensure the Petal boards are connected to each other in the proper orientation. To accommodate different separation that might arise due to component heights, compatible connectors with different mating heights can be used to further increase integration flexibility.

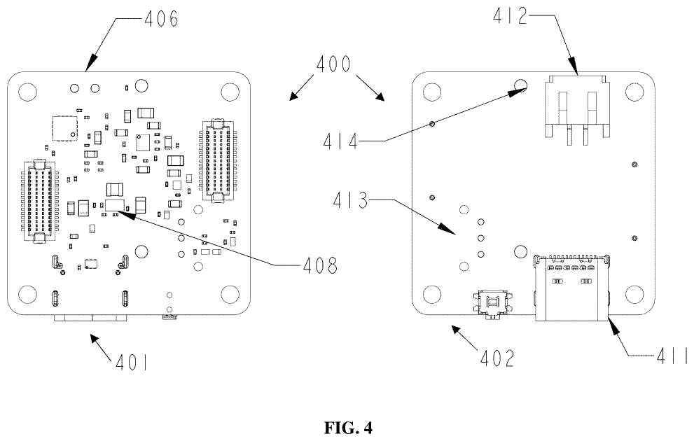

FIG. 4 is a front plan view 401 and back plan view 402 of the power Petal 400. According to FIG. 4, a power Petal is shown having exemplary printed circuit board 406 with a battery charger circuit 408. A USB connector 411 connects the battery charger circuit 408 with an external charger. The battery connector 412 connects a battery to the battery charger circuit 408. Different types of battery connectors 413 and 414 can be populated to the printed circuit board 406 to support different battery configurations.

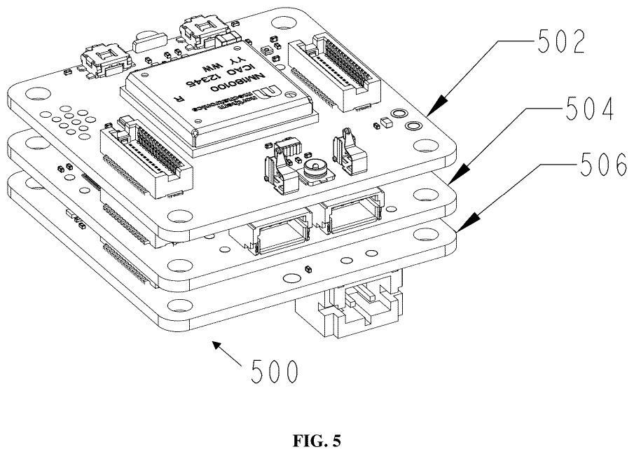

When firmware development is completed, the power Petal FIG. 4. is stacked beneath the core Petal FIG. 1 and the environment sensor Petal FIG. 2 as shown in FIG. 5. FIG. 5 is a view of the Petal core, the environment sensor Petal and the power Petal stacked together. According to FIG. 5, stacked board 500 consists of Petal core PCB 502, environment sensor Petal PCB 504 and power Petal PCB 506.

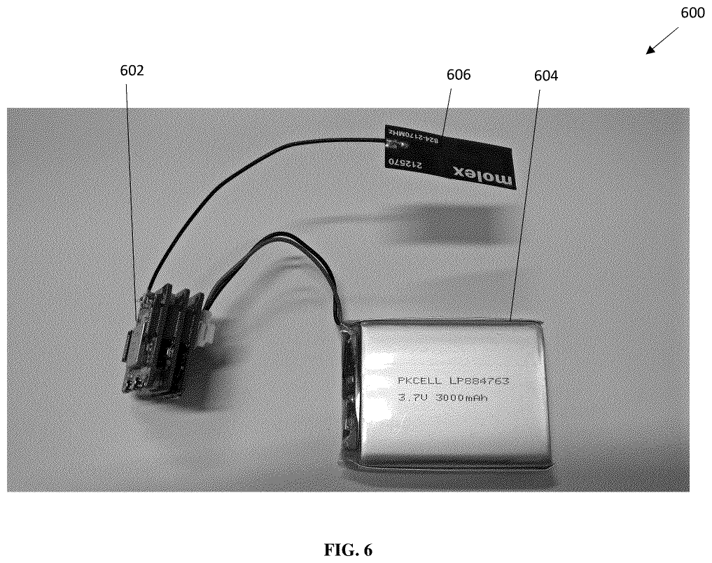

FIG. 6 is a diagram illustrating a battery connected to the core, environment sensor and power Petal stack configured for quick field deployment. According to FIG. 6, diagram 600 illustrates stacked board 602 connected to battery 604 and antenna 606. To power the entire circuit, battery 604 is connected to the stacked board 602. In the present embodiment, an off the shelf antenna 606 is connected to the Petal core through the coaxial connector 322 as shown in FIG. 3.

In the present embodiment, a rechargeable battery with lithium-ion polymer chemistry is shown. However, the power board can support non-rechargeable chemistry such as but not limited to lithium manganese oxide, lithium thionyl chloride, or nickel metal hydride.

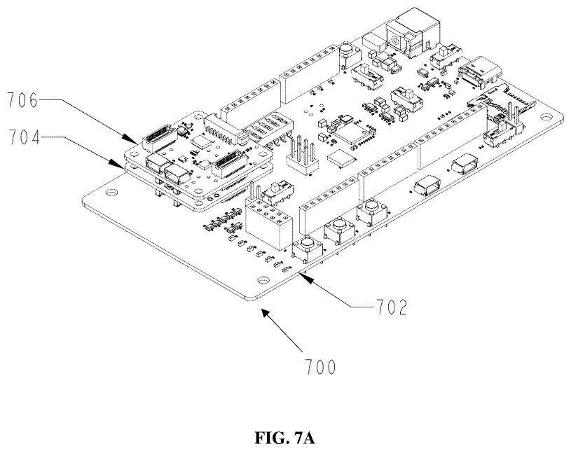

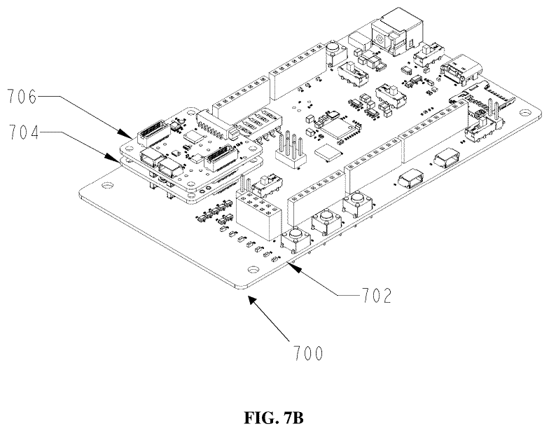

FIGS. 7A and 7B are diagrams illustrating the Petal core stacked onto a development board. FIG. 7A is a diagram illustrating a combined or integrated stacked development board. According to FIG. 7A, diagram 700 shows development board 702 with core Petal 704 and environment sensor Petal 706 stacked onto it.

According to the disclosure, FIG. 7B is a diagram illustrating an exploded view of FIG. 7A.

According to the disclosure, firmware development is carried out with the core Petal FIG. 1 and the environment sensor Petal FIG. 2 plugged onto a development board as shown in FIGS. 7A and 7B. Each Petal printed circuit board has a dimension of 30 mm width×30 mm length and 5.7 mm height. During firmware development, the Petal core is coupled to the antenna 708 on the development board 702 through the conductive spring clips 707.

The development board 702 in FIGS. 7A and 7B possesses connection to a host computer and also an on-board programmer and debugger chip to facilitate firmware development. Additional peripherals such as header connectors, push buttons, and indicator LEDs are included. The header connectors are arranged such that it is compatible with existing Arduino shields to maximize compatibility with other development ecosystems and re-use of existing hardware.

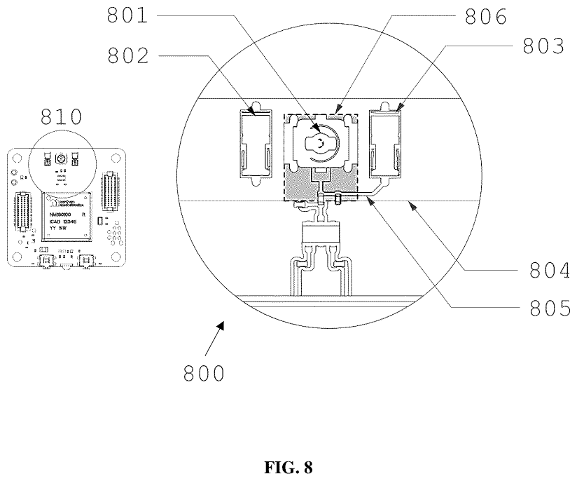

FIG. 8 is a front plan view of the Petal core 800. A close-up view 810 shows the electrical layout of the RF analog and antenna circuit. According to FIG. 8, RF signal can be coupled to the antenna through two paths either through the coaxial connector 801 or a pair of spring clips consisting of a signal clip 802 and a ground clip 803. 50 Ohms impedance is maintained in each path. In this example embodiment, the RF connection to the coaxial connector 801 makes use of a microstrip waveguide mode with the hidden patch 806 in the inner layer of the circuit board being the ground reference. The RF connection to the signal spring clip 803 is a stripline waveguide mode with 805 being the strip line and the top layer ground plane 805 being the ground reference.

According to the disclosure, one or more wireless transceivers may be included in the core Petal in addition to a processor. In the present disclosure, the core Petal has a BLE transceiver and a LoRa transceiver. Furthermore, the transceiver must couple with other system components such as external amplifiers or antenna.

According to embodiments of the disclosure, the aforementioned solution differs from all other series of prototyping boards above as follows:
Smaller form factor removes physical limitations to field deployment.
Antenna interface(s) dynamically swappable through mechanical means.
Antenna and RF front-end circuits can be snapped in any order in the stack, above or below a radio board, and continue to function.
Snap connection with mechanical retention, whereas other solutions rely on additional fasteners for mechanical retention.
Combining only the boards with circuits needed for the target application and no extraneous components, the Petal system does not result in additional power consumption, allowing prototyping using battery power for long duration field testing.
Due to the small size of the non-RF connectors, all I/O pins are exposed and thereby do not compromise the functionalities and features of the processor.

According to the disclosure, an electronic device is disclosed. The electronic device comprises one or more rigid or flexible printed circuit board (PCB), one or more RF transceivers, one or more electrically conductive contact pads, one or more matching circuits, one or more regions of conductive shapes on the PCB and one or more non-RF connectors.

According to the disclosure, two or more rigid or flexible PCB of the electronic device are configured to be modular and stackable together to create a larger integrated electronic circuit. The plurality of RF transceivers of the electronic device is coupled to the printed circuit board. The plurality of conductive contact pads is located on the top layer or the bottom layer of the printed circuit board.

According to the disclosure, the plurality of matching circuits of the electronic device is coupled between a plurality of RF transceivers and a plurality of electrically conductive contact pads. The plurality of conductive shapes of the electronic device is coupled to the plurality of conductive contact pads.

According to the disclosure, the plurality of non-RF connectors of the electronic device is coupled to the printed circuit board. At least one contact pad of the electronic device is also coupled to electrical ground.

According to the disclosure, the plurality of conductive shapes and a plurality of contact pads of the electronic device is positioned to define a gap. The plurality of conductive shapes and a plurality of contact pads are also positioned to be in direct contact.

According to the disclosure, the plurality of non-RF connectors of the electronic device is mounted on the outer layers of the printed circuit board.

According to the disclosure, the electronic device further comprises an antenna, an antenna circuit, a coaxial connector and a pair of spring clips. The pair of spring clips of the electronic device further consists of a signal clip and a ground clip.

According to the disclosure, RF signal of the electronic device is coupled to the antenna through two paths whereby impedance control is maintained in each of the paths. According to the disclosure, the electronic device maintains impedance control regardless of the way the board is connected whereby the impedance is 50 Ohms.

According to the disclosure, the two paths consist of a first path through the coaxial connector and a second path through the pair of spring clips. The RF connection to the coaxial connector of the first path utilizes a microstrip waveguide mode whereby a hidden patch in the inner layer of the circuit board is configured to be the ground reference. The RF connection to the signal spring clip of the second path utilizse a stripline waveguide mode whereby a strip line and the top layer ground plane is configured to be the ground reference.

While some embodiments or aspects of the present disclosure may be implemented in fully functioning computers and computer systems, other embodiments or aspects may be capable of being distributed as a computing product in a variety of forms and may be capable of being applied regardless of the machine or computer readable media used to affect the distribution.

At least some aspects disclosed may be embodied, at least in part, in software. is, some disclosed techniques and methods may be carried out in a computer system or other data processing system in response to its processor, such as a microprocessor, executing sequences of instructions contained in a memory, such as read-only memory (ROM), volatile random access memory (RAM), non-volatile memory, cache or a remote storage device.

The functions described herein may be stored as one or more instructions on a processor-readable or computer-readable medium. The term “computer-readable medium” refers to any available medium that can be accessed by a computer or processor. By way of example, and not limitation, such a medium may comprise RAM, ROM, EEPROM, flash memory, CD-ROM or other optical disk storage, magnetic disk storage or other magnetic storage devices, or any other medium that can be used to store desired program code in the form of instructions or data structures and that can be accessed by a computer. It should be noted that a computer-readable medium may be tangible and non-transitory. As used herein, the term “code” may refer to software, instructions, code or data that is/are executable by a computing device or processor. A “module” can be considered as a processor executing computer-readable code.

A processor as described herein can be a general-purpose processor, a digital signal processor (DSP), an application specific integrated circuit (ASIC), a field programmable gate array (FPGA) or other programmable logic device, discrete gate or transistor logic, discrete hardware components, or any combination thereof configured to perform the functions described herein. A general-purpose processor can be a microprocessor, but in the alternative, the processor can be a controller, or microcontroller, combinations of the same, or the like. A processor can also be implemented as a combination of computing devices, e.g., a combination of a DSP and a microprocessor, a plurality of microprocessors, one or more microprocessors in conjunction with a DSP core, or any other such configuration. Although described herein primarily with respect to digital technology, a processor may also include primarily analog components. For example, any of the signal processing algorithms described herein may be implemented in analog circuitry. In some embodiments, a processor can be a graphics processing unit (GPU). The parallel processing capabilities of GPUs can reduce the amount of time for training and using neural networks (and other machine learning models) compared to central processing units (CPUs). In some embodiments, a processor can be an ASIC including dedicated machine learning circuitry custom-build for one or both of model training and model inference. The disclosed or illustrated tasks can be distributed across multiple processors or computing devices of a computer system, including computing devices that are geographically distributed.

The methods disclosed herein comprise one or more steps or actions for achieving the described method. The method steps and/or actions may be interchanged with one another without departing from the scope of the claims. In other words, unless a specific order of steps or actions is required for proper operation of the method that is being described, the order and/or use of specific steps and/or actions may be modified without departing from the scope of the claims.

The specific embodiments described above have been shown by way of example and understood is that these embodiments may be susceptible to various modifications and alternative forms. Further understood is that the claims are not intended to be limited to the forms disclosed, but rather to cover all modifications, equivalents, and alternatives falling within the spirit and scope of this disclosure. While the foregoing written description of the system enables one of ordinary skill to make and use what is considered presently to be the best mode thereof, those of ordinary skill will understand and appreciate the existence of variations, combinations, and equivalents of the specific embodiment, method, and examples herein. The system should therefore not be limited by the above-described embodiment, method, and examples, but by all embodiments and methods within the scope and spirit of the system. Thus, the present disclosure is not intended to be limited to the implementations shown herein but is to be accorded the widest scope consistent with the principles and novel features disclosed herein.

Information as herein shown and described in detail is fully capable of attaining the above-described object of the present disclosure, the presently preferred embodiment of the present disclosure, and is, thus, representative of the subject matter which is broadly contemplated by the present disclosure. The scope of the present disclosure fully encompasses other embodiments which may become obvious to those skilled in the art, and is to be limited, accordingly, by nothing other than the appended claims, wherein any reference to an element being made in the singular is not intended to mean “one and only one” unless explicitly so stated, but rather “one or more.” All structural and functional equivalents to the elements of the above-described preferred embodiment and additional embodiments as regarded by those of ordinary skill in the art are hereby expressly incorporated by reference and are intended to be encompassed by the present claims.

Moreover, no requirement exists for a system or method to address each problem sought to be resolved by the present disclosure, for such to be encompassed by the present claims. Furthermore, no element, component, or method step in the present disclosure is intended to be dedicated to the public regardless of whether the element, component, or method step is explicitly recited in the claims. However, various changes and modifications in form, material, work-piece, and fabrication material detail may be made, without departing from the spirit and scope of the present disclosure, as set forth in the appended claims, as may be apparent to those of ordinary skill in the art, are also encompassed by the present disclosure.

What is claimed is:

1. An electronic device comprising:
one or more rigid or flexible printed circuit boards (PCBs);
one or more RF transceivers;
one or more electrically conductive contact pads;
one or more matching circuits;
one or more regions of conductive shapes on the PCB; and
one or more non-RF connectors;
wherein two or more rigid or flexible PCB are configured to be modular and stackable together to create a larger integrated electronic circuit.

2. The electronic device of claim 1, wherein the plurality of RF transceivers is coupled to the printed circuit board.

3. The electronic device of claim 1, wherein the plurality of conductive contact pads is located on the top layer or the bottom layer of the printed circuit board.

4. The electronic device of claim 1, wherein the plurality of matching circuits is coupled between a plurality of RF transceivers and a plurality of electrically conductive contact pads.

5. The electronic device of claim 1, wherein the plurality of conductive shapes is coupled to the plurality of conductive contact pads.

6. The electronic device of claim 1, wherein the plurality of non-RF connectors is coupled to the printed circuit board.

7. The electronic device of claim 2, wherein at least one contact pad is coupled to electrical ground.

8. The electronic device of claim 1, wherein the plurality of conductive shapes and a plurality of contact pads are positioned to define a gap.

9. The electronic device of claim 1, wherein the plurality of conductive shapes and a plurality of contact pads are positioned to be in direct contact.

10. The electronic device of claim 1, wherein the plurality of non-RF connectors is mounted on the outer layers of the printed circuit board.

11. The electronic device of claim 1 further comprising an antenna, an antenna circuit, a coaxial connector and a pair of spring clips.

12. The electronic device of claim 11 wherein the pair of spring clips further consist of a signal clip and a ground clip.

13. The electronic device of claim 11 wherein RF signal of the electronic device is coupled to the antenna through two paths whereby impedance control is maintained in each of the paths.

14. The electronic device of claim 13 wherein the two paths consist of a first path through the coaxial connector and a second path through the pair of spring clips.

15. The electronic device of claim 14 wherein the RF connection to the coaxial connector of the first path utilizes a microstrip waveguide mode whereby a hidden patch in the inner layer of the circuit board is configured to be the ground reference.

16. The electronic device of claim 14 wherein the RF connection to the signal spring clip of the second path utilizes a stripline waveguide mode whereby a strip line and the top layer ground plane is configured to be the ground reference.

17. The electronic device of claim 13 wherein the electronic device maintains impedance control regardless of the way the board is connected.

18. The electronic device of claim 13 whereby the impedance is 50 Ohms.
